(19) United States
(12) Patent Application Publication
(10) Pub. No.: US 2005/0277286 A1
(43) Pub. Date: Dec. 15, 2005

(54) Metallic glass microtool

(76) Inventor: Daewoong Suh, Phoenix, AZ (US)

Correspondence Address: Michael A. Bernadicou;BLAKELY, SOKOLOFF, TAYLOR & ZAFMAN LLP, Seventh Floor, 12400 Wilshire Boulevard, Los Angeles, CA, 90025, US

(21) Appl. No.: 10/868,440

(22) Filed: Jun. 14, 2004

(51) Int. Cl. H01L 21/4763

(52) U.S. Cl. 438/637

(57) ABSTRACT

Embodiments of the invention provide microtool made at least partially from a metallic glass material. The metallic glass material may allow formation of smaller features than achieved with other materials. The microtool may be used in some embodiments to form a package substrate with small feature sizes.

### BACKGROUND

### BACKGROUND OF THE INVENTION

A semiconductor die contains the active elements that comprise an integrated circuit such as a microprocessor. Semiconductor dies are typically very small and have a large number of signal and power contacts. Because of the small size of the die, a package substrate is typically used to effectively enlarge the area over which connections may be made with the die. The die is usually mounted to one side of the package substrate, while the other side is coupled to several interconnect devices, such as pins, balls, etc., which then allow the completed package to be mounted into a socket or another device on a printed circuit board (PCB). Interconnects within the package substrate electrically connect the die to the interconnect devices.

A package substrate typically includes a metal or organic core, and dielectric layers on top of the core that insulate conductors forming interconnects. The process of forming the package substrate typically begins with providing the core, and forming a dielectric layer on either side of the core. The dielectric layers may then be etched to form troughs, which will then be filled with a conductive material, such as copper, to form an interconnect. More dielectric layers may be formed on top of the package substrate as necessary to provide adequate communication with the die.

Recently, microtools have been developed to impress a pattern into the package substrate. A microtool is a small tool that is patterned so that when it is pressed against a layer, the pattern will be impressed in the layer. Raised areas of the pattern may form the troughs that are filled with a conductive material to form interconnects. Microtools are now typically formed from pure nickel.

### BRIEF DESCRIPTION OF THE DRAWINGS

FIGS. 1a and 1b illustrate a microtool according to one embodiment of the invention.

FIG. 2 is a flow chart that illustrates a process for forming a microtool.

FIG. 3 is a cross sectional side view that illustrates a master mold.

FIG. 4 is a cross sectional side view that illustrates the heated metallic glass material.

FIG. 5 is a cross sectional side view that illustrates the heated metallic glass material being pressed into the master mold.

FIG. 6 is a cross sectional side view that illustrates the microtool removed from the master mold.

FIG. 7 is a flow chart that illustrates a process for using the microtool to imprint a material such as a package substrate.

FIG. 8 is a cross sectional side view that illustrates a substrate core.

FIG. 9 is a cross sectional side view that illustrates a package substrate including a core and dielectric layer.

FIG. 10 is a cross sectional side view that illustrates a patterned dielectric layer.

FIG. 11 is a cross sectional side view that illustrates interconnects formed in the indentations of the dielectric layer.

FIG. 12 is a schematic diagram of a computer system.

### DETAILED DESCRIPTION

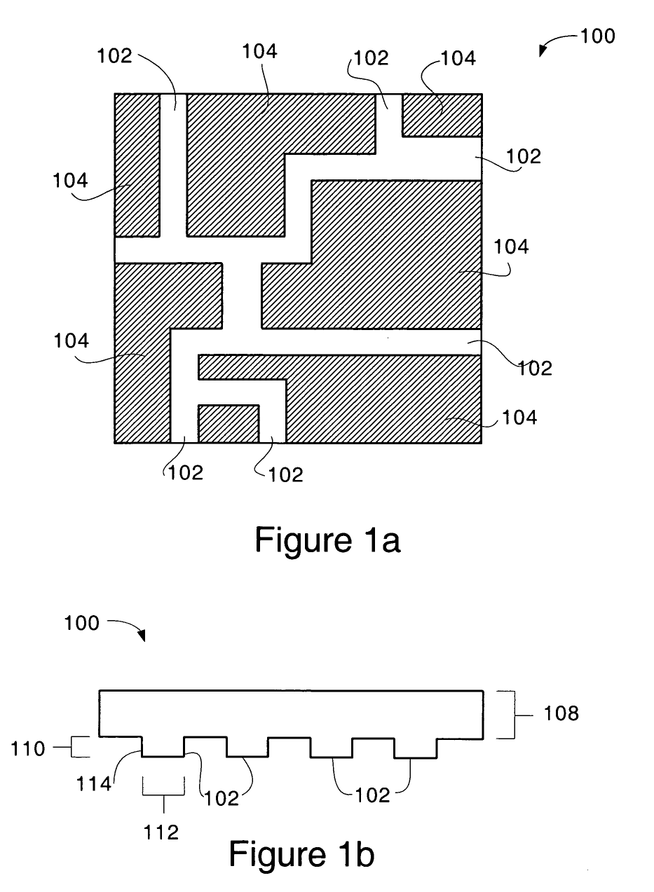

FIGS. 1a and 1b illustrate a microtool 100 according to one embodiment of the invention. FIG. 1a illustrates an overhead view of a microtool 100 and FIG. 1b illustrates a cross-sectional view of the microtool 100. As can be seen in FIG. 1a, the microtool 100 may includes raised portions 102 and recessed portions 104. When pressure is applied to the backside of the microtool 100, and the microtool 100 is pressed against a dielectric or other soft layer, the raised portions 102 may impress a pattern in the dielectric layer. The microtool 100 may be patterned such that the areas where interconnects are to be formed on the package substrate correspond to the raised areas 102 of the microtool 100. The raised portions 102 may thus define features that will be impressed upon a package substrate or other piece of material. It is understood that the microtool 100 may include a pattern for patterning a single package substrate, however, in practice the microtool 100 may include a pattern to pattern several package substrates or other pieces of material at once.

FIG. 1b is a cross sectional side view of a microtool 100 according to one embodiment of the present invention. As shown in FIG. 1b, the surface of the microtool 100 has raised portions 102 that may impress a pattern upon a dielectric layer or other material. The microtool 100 may have a base portion 108 and a patterned portion 110. The patterned portion 110 may be the raised areas 102 of the microtool 100 that form the pattern to be transferred to the substrate or other piece of material. The base portion 108 may be the rest of the microtool 100 above which the raised areas 102 extend.

In some embodiments, the microtool 100 may comprise a single piece of material. In other embodiments, different materials may make up portions of the microtool 100. For example, the patterned portion 110 may comprise a first material, and all or part of the base portion 108 may comprise a second material. In one embodiment, a part of the base portion 108 further from the patterned portion 110 may comprise a layer of a first material as a substrate material while a part of the base portion 108 closer to the patterned portion as well as the patterned portion 110 may comprise a second material, such as a bulk metallic glass material, attached to the substrate material.

In some embodiments, the microtool 100 may comprise a bulk metallic glass material. In the past, metallic glass materials could only be formed in thin ribbons due to the extremely fast cooling rates of around 10⁵ to 10⁶ degrees Celsius per second between the melting temperature Tₘ and the glass transition temperature (T_{g}) required to make such materials. Such ribbons were less than about 100 microns in thickness, to allow the extremely fast cooling rates. Further, if such materials were raised in temperature to a temperature above the glass transition temperature and below the melting temperature, they would quickly crystallize.

More recently, bulk metallic glass material has been made with cooling rates of about 100 degrees Celsius per second to about 1 degree Celsius per second when cooling the material from Tₘ to T_{g}. Such lower cooling rates allow the creation of larger pieces of metallic glass material (“bulk” metallic glass material). The bulk metallic glass materials also allow holding the temperature of the material between Tₘ and T_{g} without substantial crystal formation in the material.

Such bulk metallic glass materials may have a substantially amorphous structure during cooling between their melting temperature and glass transition temperature and once they have been cooled below the glass transition temperature. That is, while most metals have a crystalline structure, such bulk metallic glass materials may have atoms that are less ordered.

Some bulk metallic glass materials that may be used as a material of the microtool 100 include (percentages are atomic percentages): an alloy containing 40% palladium, 30% copper, 10% nickel, and 20% phosphorus, which has a glass transition temperature of about 304 degrees Celsius; 55% lanthanum, 25% aluminum, and 20% nickel, which has a glass transition temperature of about 208 degrees Celsius; 65% zirconium, 7.5% aluminum, and 27.5% copper, which has a glass transition temperature of about 367 degrees Celsius; 52.5% zirconium, 10% aluminum, 5% titanium, 17.9% copper, and 14.6% nickel, which has a glass transition temperature of about 358 degrees Celsius; 55% zirconium, 10% aluminum, 5% nickel, and 30% copper, which has a glass transition temperature of about 412 degrees Celsius; and 65% zirconium, 10% aluminum, 10% nickel, and 15% copper, which has a glass transition temperature of about 379 degrees Celsius. Different bulk metallic glass materials may also be used. For example, different atomic percentages of each element may be used in the alloys mentioned above. Other bulk metallic glass materials, such as other Mg-based bulk metallic glass materials, La-based bulk metallic glass materials, Pd-based bulk metallic glass materials, Zr-based bulk metallic glass materials, Ti-based bulk metallic glass materials, Fe—P-based bulk metallic glass materials, Fe—B-based bulk metallic glass materials, or other materials.

Bulk metallic glass materials used as all or part of the microtool 100 may have material properties that allow superplastic flow when the bulk metallic glass material is at a temperature between the melting temperature and the glass transition temperature of the material. This ease of flow of the bulk metallic glass material may allow the raised areas 102 of the microtool 100 to be formed using low pressures and with very small feature sizes. A feature size may be, for example a width of a raised area, such as feature 114 that has a very small width 112. For example, in some embodiments the microtool 100 may include a feature 114 with a width 112 less than about one micron (while a “width” is mentioned, other feature dimensions such as length, etc. may be of similar size). In some embodiments the microtool 100 may include a feature 114 with a width 112 less than about 0.5 microns. In other embodiments, the microtool 100 may include a feature 114 with a width 112 between about 0.5 microns and about 0.2 microns. Such features may be transferred to the package substrate or other piece of material to be patterned with the microtool, such that the package substrate or other piece of material may have features of about the same sizes after patterning.

Additionally, such bulk metallic glass materials may have a hardness much higher than materials normally used in microtools. This may allow the microtool 100 to have a higher hardness than previously, which increases the wear resistance of the microtool 100. This increased wear resistance may allow the microtool 100 to last longer (more imprinting cycles) and form better impressions on a package substrate than previous microtools.

For example, Mg-based bulk metallic glass materials and La-based bulk metallic glass materials may have a hardness on the Vickers scale of about 750 to about 1000, Pd-based bulk metallic glass materials may have a hardness on the Vickers scale of about 1500 to about 1750, Zr-based bulk metallic glass materials may have a hardness on the Vickers scale of about 1600 to about 1800, Ti-based bulk metallic glass materials may have a hardness on the Vickers scale of about 2200 to about 2400, Fe—P-based bulk metallic glass materials may have a hardness on the Vickers scale of about 2900 to about 3100, and Fe—B-based bulk metallic glass materials may have a hardness on the Vickers scale of about 4200 to about 4400. Each of these materials may provide a higher hardness, and thus wear better, than previous microtool materials.

According to a further embodiment of the invention, the bulk metallic glass material of the microtool 100 may include crystalline volumes of material within the amorphous material. These crystalline volumes may be the same material composition as the amorphous material, but simply be crystallized precipitates. In some embodiments, the bulk metallic glass material of the micro tool 100 may include 1% or less of these crystalline precipitates.

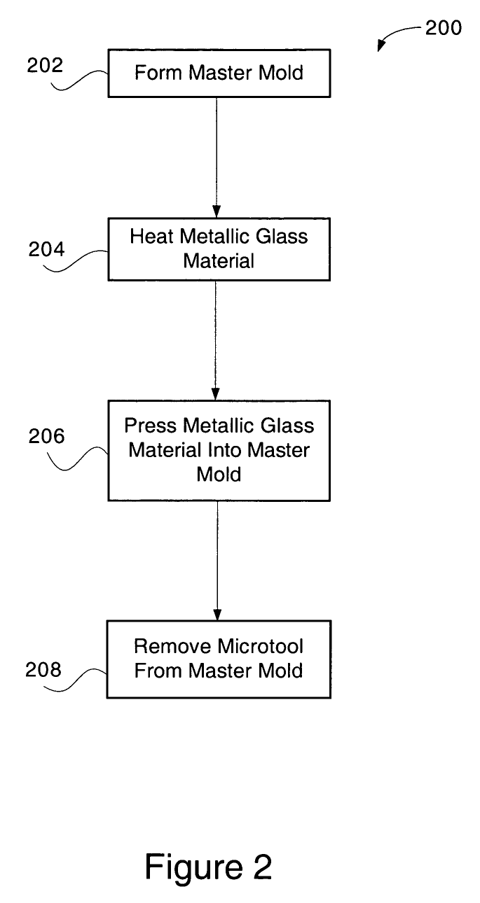

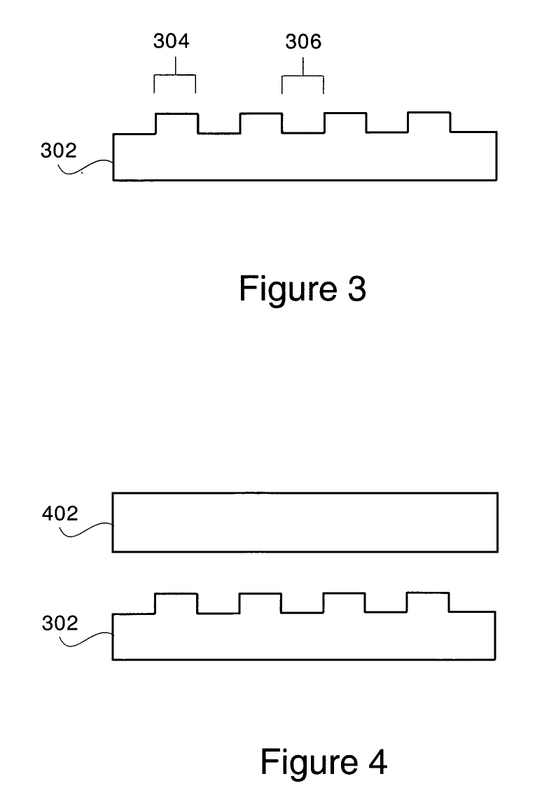

FIG. 2 is a flow chart 200 that illustrates a process for forming a microtool 100 according to one embodiment of the present invention. In other embodiments, some of the steps shown in the flow chart 200 may be omitted, other steps may be added, and/or the steps shown may be performed in a different order. FIGS. 3-6 are cross sectional side views that illustrate the formation of a microtool 100 as described in FIG. 2.

A master mold including a pattern may be formed 202. FIG. 3 is a cross sectional side view that illustrates a master mold 302 that is patterned to mirror the desired microtool pattern. Since the microtool 100 may be formed on the mold 302, the mold 302 may be created using a pattern complementary to that of the desired microtool 100. The pattern of the mold 302 may include raised features 304, which may result in the recessed portions 104 of the microtool 100, and may include recessed features 306, which may result in the raised portions 102 of the microtool 100 pattern. In some embodiments, the features 304, 306 may have dimensions, such as length, width, etc. that are smaller than about 1.0 micron. In an embodiment, the features 304, 306 may have dimensions less than about 0.5 microns. In other embodiments, the features 304, 306 may have dimensions between about 0.5 microns and about 0.2 microns. These feature sizes may be transferred from the mold 302 to the microtool 100.

The mold 302 may comprise photoresist, silicon, or other materials that can be patterned. If the mold 302 is photoresist, the mold 302 may be patterned using common photolithographic techniques. For example, a deposited layer of photoresist may be exposed to light through a mask that includes the pattern. After the layer of photoresist has been exposed, if the photoresist is a positive photoresist, the exposed areas will soften, and the softened areas may be removed using a specifically chosen selective etch. After the resist layer has been etched, the mold 302 has been formed. A similar process can be used to form the mold 302 from silicon or other materials. A layer of photoresist may be deposited on top of the layer of silicon or other material to perform the photolithography. After the resist has been deposited over the silicon or other material, the resist may be exposed through a mask forming a pattern, and the exposed portions of the resist are removed. The silicon underlying the removed resist may then be etched using a selective etch chosen to remove the exposed silicon. After the silicon has been etched, the photoresist is removed, and the mold 302 has been formed.

Returning to FIG. 2, a piece of bulk metallic glass material may be heated 204 to a temperature between the glass transition temperature of the material and the melting temperature of the material. FIG. 4 is a cross sectional side view that illustrates the heated 204 bulk metallic glass material 402 near the mold 302. Such heating may be performed by any suitable method and equipment.

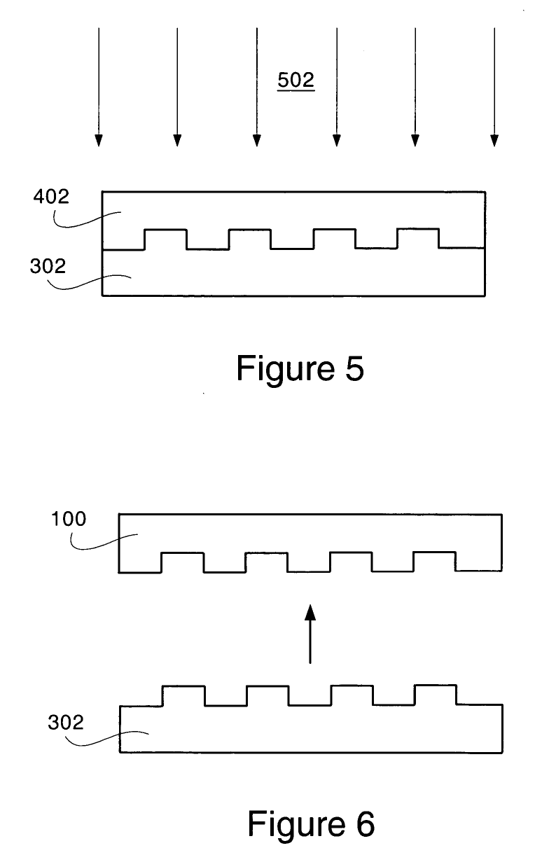

Returning again to FIG. 2, the heated bulk metallic glass material 402 may be pressed 206 into the master mold 302. FIG. 5 is a cross sectional side view that illustrates the heated 204 bulk metallic glass material 402 being pressed 206 into the master mold 302 by pressure 502. Bulk metallic glass materials such as that used to form the microtool 100 may exhibit superplastic behavior when in a temperature range between the glass transition temperature and the melting temperature. This may allow the heated bulk metallic glass material 402 to flow into the features of the master mold 302 to form an accurate mirror image of the pattern on the master mold 302 with relatively low pressure. For example, in some embodiments, the pressure 502 used to press 206 the heated bulk metallic glass material 402 the master mold 302 may be in a range from about 1 megapascal to about 100 megapascals. In other embodiments, the pressure 502 may be in a range from about 2 megapascals to about 10 megapascals.

As described above, some bulk metallic glass materials 402 that may be used may have relatively low glass transition temperatures. Some of the described materials 402 have glass transition temperatures between about 208 degrees Celsius and about 412 degrees Celsius. Thus, pressing 206 the heated bulk metallic glass material 402 into the master mold 302 may be done at relatively low temperatures in some embodiments. In other embodiments, temperatures significantly above the glass transition temperature of a material 402 may be used, which may allow the same strain rate in the material with lower pressures used than if lower temperatures were used. Alternatively, higher temperatures may allow the same strain rate to be achieved with lower pressures 502. For example, an alloy containing 40% palladium, 30% copper, 10% nickel, and 20% phosphorus may have a glass transition temperature of about 304 degrees Celsius. Such an alloy may provide a much higher strain rate with 2 megapascals of stress applied a temperature between about 367 degrees Celsius than the strain rate achieved with 10 megapascals of stress applied at about 307 degrees Celsius.

In other embodiments, other methods to transfer the pattern from the master mold 302 to the bulk metallic glass material 402 may be used. For example, an injection molding process may be used in some embodiments.

Returning now to FIG. 2, the formed microtool 100 may be removed 208 from the master mold 302. FIG. 6 is a cross sectional side view that illustrates the microtool 100 removed 208 from the master mold 302. The bulk metallic glass material of the microtool 100 may be cooled below its glass transition temperature prior to removing the tool 100 from the master mold 302 in some embodiments. The result may be a patterned microtool 100 that exhibits increased hardness, and as a result reduced wear, over previous microtools 100, thereby increasing the life of the microtool 100 and dramatically reducing the cost of the microtool 100 as well as increasing the accuracy of the package substrate or other imprinting process.

In some embodiments, crystalline regions may be formed in the bulk metallic glass material of the microtool 100. This may be done before or after the microtool 100 is removed 208 from the master mold 302. The crystalline regions may be formed by raising or keeping the temperature of the metallic glass material above the glass transition temperature but below the melting temperature for a period of time. In some embodiments, the temperature of the bulk metallic glass material may be held at a temperature significantly above the glass transition temperature and close to the melting temperature for a time period in a range of about one to ten hours. Such crystalline regions may provide the microtool 100 with greater strength and toughness.

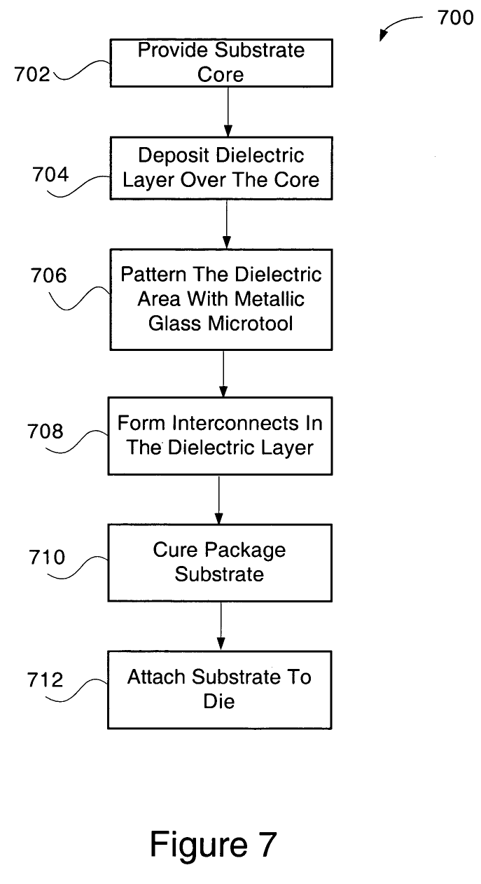

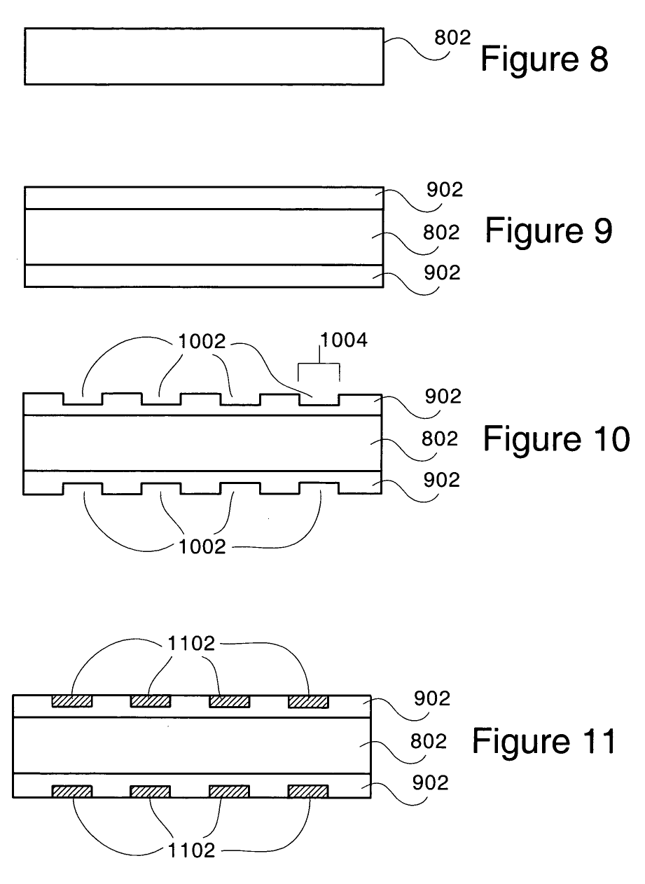

FIG. 7 is a flow chart 700 that illustrates a process for using the microtool 100 to imprint a material such as a package substrate or other substrate according to one embodiment of the present invention. Such a patterning may be part of a process to form an interconnect structure, such as that used in a package substrate. The process is described as being used to form a package substrate, although other components may be patterned using similar processes. FIGS. 8-11 further illustrate the process described in FIG. 7 with respect to a package substrate.

A substrate core may be provided 702. FIG. 8 is a cross sectional side view that illustrates a substrate core 802. The substrate core 802 may be a metallic or organic material that has been chosen to provide strength for the package substrate. The core 802 may include one or more vias to facilitate electrical communication between the top side and the bottom side of the package substrate. The vias (not shown) may be formed by drilling holes in the core 802, and filling the holes with a conductive material such as copper. The vias can then connect with the interconnects that will be formed in the dielectric layers. The vias may facilitate communication between the semiconductor die and the interconnect devices in the semiconductor package.

Returning to FIG. 7, a dielectric layer may be deposited 704 over the core 802. FIG. 9 is a cross sectional side view that illustrates a package substrate including a core 802 and dielectric layer 902 deposited on either side of the core 702. The dielectric layers 902 may be epoxy or another appropriate material, and may be deposited using spin-on deposition, etc. The material comprising the dielectric layers 902 may be deformable by the microtool 100.

Referring again to FIG. 7, the dielectric layers 902 may be patterned 706 using a microtool 100 at least partially comprising a bulk metallic glass material. FIG. 10 is a cross sectional side view that illustrates a patterned dielectric layer 902. The indentations 1002 in the dielectric layer 902 may be formed by pressing the microtool 100 against the dielectric layer 902. The indentations 1002 may be features that have dimensions approximately equal to the feature sizes of the microtool 100. Thus, for example, an indentation 1002 may have a width 1004, among other sizes, of less than about 1.0 microns, less than about 0.5 microns, or between about 0.5 microns and about 0.2 microns.

Returning to FIG. 7, interconnects may be formed 708 in the dielectric layer 902. FIG. 11 is a cross sectional side view that illustrates interconnects 1102 formed 708 in the indentations 1002 of the dielectric layer 902. The interconnects 1102 may allow for communication with the die. Such interconnects 1102 may be formed 708 by depositing a seed layer over the dielectric layer 902. The seed layer may be used during an electroplating process to provide current to areas of the dielectric layer that will be electroplated. The seed layer may comprise any appropriate conductive material, such as copper, titanium, etc, and may be deposited using any appropriate process including sputtering, chemical vapor deposition (CVD), etc. The dielectric layer 902 may then be electroplated to form the interconnects 1102 in the dielectric layer 902. The electroplated metal may form the interconnects 1102 to communicate with the semiconductor die. The metal may be any conductive material, including aluminum, copper, etc. The electroplated metal may then be polished back to the dielectric layer 902 to isolate and form the interconnects 1102. The metal can be polished back using chemical mechanical polishing (CMP) or any other appropriate method for planarizing.

The interconnects 1102 may also be coupled to vias which connect with vias in the core 802 to allow for communication between interconnects formed on the top of the package substrate and interconnects attached to the bottom of the package substrate. More dielectric layers may be deposited on top of the dielectric layers 902 and the interconnects 1102 to create more layers of interconnects. The top dielectric layer of the package substrate may have openings formed in it to create pads coupled to vias that are to contact ball grid array (BGA) balls or other interconnects between the die and the package substrate.

Returning again to FIG. 7, the package substrate may be cured 710 to harden its materials. The package substrate may then be attached 712 to a microelectronic die, such as a microprocessor, to form a die-substrate assembly.

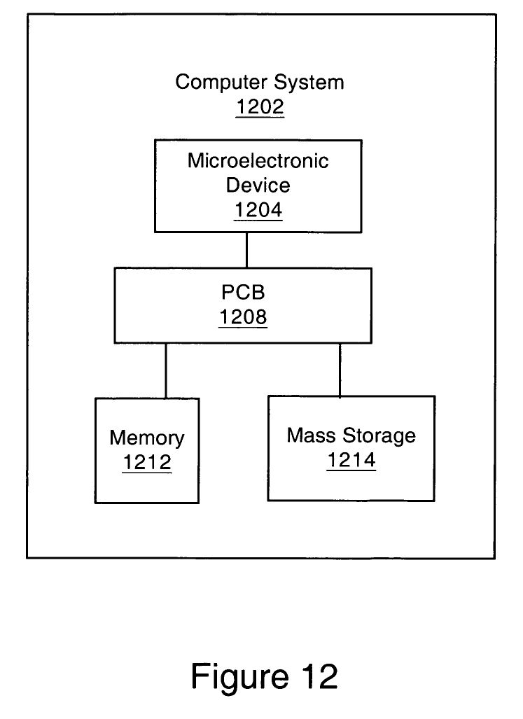

FIG. 12 is a schematic diagram of a computer system 1202 according to one embodiment of the present invention. The computer system 1202 may include the die-substrate assembly, in which a package substrate has been made through use of the microtool 100 and then attached to a die. The die-substrate assembly may make up a microelectronic device 1204 that may comprise part of the computer system 1202.

The microelectronic device 1204 of the computer system 1202 may be connected to a structure such as a printed circuit board (“PCB”) 1208 by connectors such as solder balls or other connectors. Additionally, the computer system 1202 may include a memory 1212 and/or a mass storage unit 1214, which may be connected to the PCB 1208. The memory 1212 may be any memory, such as random access memory, read only memory, or other memories. The mass storage unit 1214 may be a hard disk drive, an EEPROM, or another mass storage device. The computer system 1202 may also include other components such as input/output units, a microprocessor, or other components. The computer system 1202 may be a “personal computer” such as are commonly used by individuals and businesses. Alternatively, the computer system 1202 may be other types of computers, such as a wireless phone having a microprocessor, memory, and/or other components.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

1. An imprinting tool, comprising:
a base portion;
a patterned portion to impress a pattern on a substrate; and
wherein at least one of the base portion or the patterned portion comprises a metallic glass material having an at least partially amorphous structure.

2. The device of claim 1, wherein the metallic glass material is chosen from the group consisting of an alloy including palladium, copper, nickel, and phosphorus, an alloy including lanthanum, aluminum, and nickel, an alloy including zirconium, aluminum, and copper, and an alloy including zirconium, aluminum, titanium, copper, and nickel.

3. The device of claim 1, wherein the metallic glass material is at least partially crystalline.

4. The device of claim 1, wherein the pattern is to pattern an interconnect structure.

5. The device of claim 4, wherein the substrate is a package substrate.

6. The device of claim 1, wherein the patterned portion has a Vickers hardness of 1000 or greater.

7. The device of claim 1, wherein the patterned portion includes a feature with a width of about 0.5 microns or less.

8. The device of claim 7, wherein the patterned portion includes a feature with a width in a range between about 0.5 microns and about 0.2 microns.

9. A method, comprising:
heating a metallic glass material to a temperature between the glass transition temperature of the material and the melting temperature of the material; and
transferring a pattern from a master mold to the metallic glass material.

10. The method of claim 9, wherein the metallic glass material is chosen from the group consisting of an alloy including palladium, copper, nickel, and phosphorus, an alloy including lanthanum, aluminum, and nickel, an alloy including zirconium, aluminum, and copper, and an alloy including zirconium, aluminum, titanium, copper, and nickel.

11. The method of claim 9, wherein the metallic glass material has a substantially amorphous structure.

12. The method of claim 11, further comprising forming crystalline portions of the metallic glass material.

13. The method of claim 12, wherein forming crystalline portions comprises holding the metallic glass material at a temperature between the glass transition temperature of the material and the melting temperature of the material until at least a portion of the metallic glass material forms crystal structures.

14. The method of claim 9, wherein transferring the pattern from the master mold to the metallic glass material comprises pressing the heated metallic glass material against the master mold to transfer a pattern from the master mold to the metallic glass material.

15. The method of claim 14, wherein pressing the heated metallic glass material against the master mold comprises applying a stress in a range from about 2.0 megapascals to about 10.0 megapascals.

16. The method of claim 9, wherein transferring the pattern from the master mold to the metallic glass material comprises injecting the heated metallic glass material into an injection mold that comprises the master mold.

17. The method of claim 9, wherein the pattern includes a feature with a width of about 0.5 microns or less.

18. The method of claim 17, wherein the pattern includes a feature with a width in a range between about 0.5 microns and about 0.2 microns.

19. A method, comprising:
providing a substrate core;
depositing a dielectric layer over the core; and
patterning the dielectric layer using a microtool that comprises a metallic glass material.

20. The method of claim 19, wherein patterning the dielectric comprises pressing the microtool against the dielectric layer.

21. The method of claim 19, further comprising:
depositing a seed layer over the dielectric layer; and
electroplating the dielectric layer to form interconnects in the dielectric layer.

22. The method of claim 22, wherein the substrate core, patterned dielectric layer, and interconnects comprise a package substrate, and further comprising:
attaching the package substrate to a microelectronic die to form a die-substrate assembly; and
attaching the die-substrate assembly to a printed circuit board.

23. The method of claim 19, wherein patterning the dielectric comprises pressing the microtool against the dielectric layer to form a feature on the dielectric layer with a width of about 0.5 microns or less.

24. The method of claim 23, wherein patterning the dielectric comprises pressing the microtool against the dielectric layer to form a feature on the dielectric layer with a width in a range between about 0.5 microns and about 0.2 microns.

25. The method of claim 19, wherein the metallic glass material is chosen from the group consisting of an alloy including palladium, copper, nickel, and phosphorus, an alloy including lanthanum, aluminum, and nickel, an alloy including zirconium, aluminum, and copper, and an alloy including zirconium, aluminum, titanium, copper, and nickel.

26. The method of claim 19, further comprising:
heating the metallic glass material to a temperature between the glass transition temperature of the material and the melting temperature of the material; and
transferring a pattern from a master mold to the metallic glass material of the microtool.

27. The method of claim 26, wherein the metallic glass material has a substantially amorphous structure.
